(19) United States
(12) Patent Application Publication
(10) Pub. No.: US 2005/0040508 A1
(43) Pub. Date: Feb. 24, 2005

(54) Area array type package stack and manufacturing method thereof

(76) Inventor: Jong-Joo Lee, Suwon-si (KR)

Correspondence Address: HARNESS, DICKEY & PIERCE, P.L.C., P.O. BOX 8910, RESTON, VA, 20195, US

(21) Appl. No.: 10/798,943

(22) Filed: Mar. 12, 2004

(30) Foreign Application Priority Data
Aug. 22, 2003 (KR) 2003-58273

(51) Int. Cl. H01L 21/48; H01L 23/52

(52) U.S. Cl. 257/686; 438/109; 257/692; 257/774; 257/786; 438/612

(57) ABSTRACT

A package stack has at least two packages of area array types (AAT), each having connecting pads. A flexible cable having conductive patterns is provided between the AAT packages and electrically connected to the connecting pads of the packages.

### CROSS REFERENCE TO RELATED APPLICATIONS

This U.S. non-provisional application claims priority under 35 U.S.C. §119 to Korean Patent Application No. 2003-58273 filed Aug. 22, 2003, the contents of which are incorporated by reference.

### BACKGROUND OF THE PRESENT INVENTION

A kind of packaging technology generally known in the Background Art is a three-dimensional stacking. Such stacking technology, including chip stacking and package stacking, serves to increase the number of chips or packages per unit area of the motherboard (or, in other words, to increase density).

A typical chip stack package 100, also referred to as a multi-chip package (MCP), is shown in FIG. 1, according to the Background Art. Referring to FIG. 1, chip stack package 100 has two chips 101 and 102 stacked on a common substrate 105. Respective chips 101 and 102 are electrically connected to substrate 105 through bond wires 103 and 104. An encapsulating body 107 protects chips 101 and 102 and wires 103 and 104 from the environment. Solder balls 106 are arranged under substrate 105 to provide electrical paths to and from external systems.

Chip stack package 100 has structural benefits such as a reduced package size and an increase mounting density. However, chip stack package 100 encounters potential reliability test failures and resultant yield losses. In order to avoid these issues, package stacking is considered to be an option for the three-dimensional stacking because burn-in and tests are available before stacking. The ability to package and test the chips prior to stacking allows for minimizing chip yield loss.

Another variety of packaged stack according to the Background Art is shown as chip stack package 800 in FIG. 2. Package stack 800 in FIG. 2 is composed of four ball grid array (BGA) packages 802. Each BGA package has a single chip 811 attached on a central region of a substrate 820. Chip 811 is electrically connected to wiring patterns 850 formed on or in substrate 820 through bond wires or tape leads 822. Wiring patterns 850 are also electrically and mechanically joined to solder balls 837 disposed on a peripheral region of substrate 820. To stack lower and upper packages, solder balls 837 of the upper package are connected to contact pads 841 of the lower package.

Like BGA package stack 800, a stack configuration of area array type packages has in general a structural linitation. Specifically, input/output terminals such as the solder balls cannot be arranged underneath the chip-attached region of the substrate and therefore should be located at the peripheral region of the substrate. Unfortunately, this causes an increase in package size and a decrease in mounting density.

Such concerns are relevant to more recently developed package types such as a chip scale package (CSP). A variety of CSP is an area array package stack in which the input/output terminals are arranged all over the bottom face of the substrate and for which package stacking is possible. FIG. 3 shows an area array type package stacks 700 according to the Background Art.

Referring to FIG. 3, area array package 700 includes solder balls 703 arranged under each package and electrically connected to contact pads 705 of a lower package. Contact pads 705 are formed on a flexible cable 702, which extends from the top face around circumferential edges to the bottom face of chip 701.

### SUMMARY OF THE PRESENT INVENTION

At least one embodiment of the present invention provides a stack of area array type packages, such as ball grid array (BGA) packages, that can reduce interconnection paths from each package to external connection terminals and also can reduce the height of the package stack.

At least one other embodiment of the present invention provides an area array type package stack comprising at least two packages of area array type disposed to form a stack. Each package comprises a substrate having a first face, a second face opposing the first face, a plurality of terminal pads, and a plurality of connecting pads formed on the second face. Each package further comprises a semiconductor chip attached to the first face of the substrate and electrically connected to the terminal pads and the connecting pads. The package stack further comprises at least one flexible cable having a plurality of conductive patterns thereon, extending around at least one side edge of a lower one of the packages, and electrically connecting the connecting pads of the packages through the conductive patterns.

At least one other embodiment of the present invention provides a method for manufacturing an area array type package stack. Such a method may include: providing a first individual package of an area array type (AAI) on a flexible cable wherein connecting pads under the AAT package are electrically connected to conductive patterns on the flexible cable; bending the flexible cable to surround at least one side edge of the package; and stacking a second AAT package on the first AAT package wherein connecting pads under the second package are electrically connected to the conductive patterns on the flexible cable.

Additional features and advantages of the invention will be more fully apparent from the following detailed description of example embodiments, the accompanying drawings and the associated claims.

### BRIEF DESCRIPTION OF THE DRAWINGS

FIG. 1 is a cross-sectional view schematically showing a conventional chip stack package, according to the Background Art.

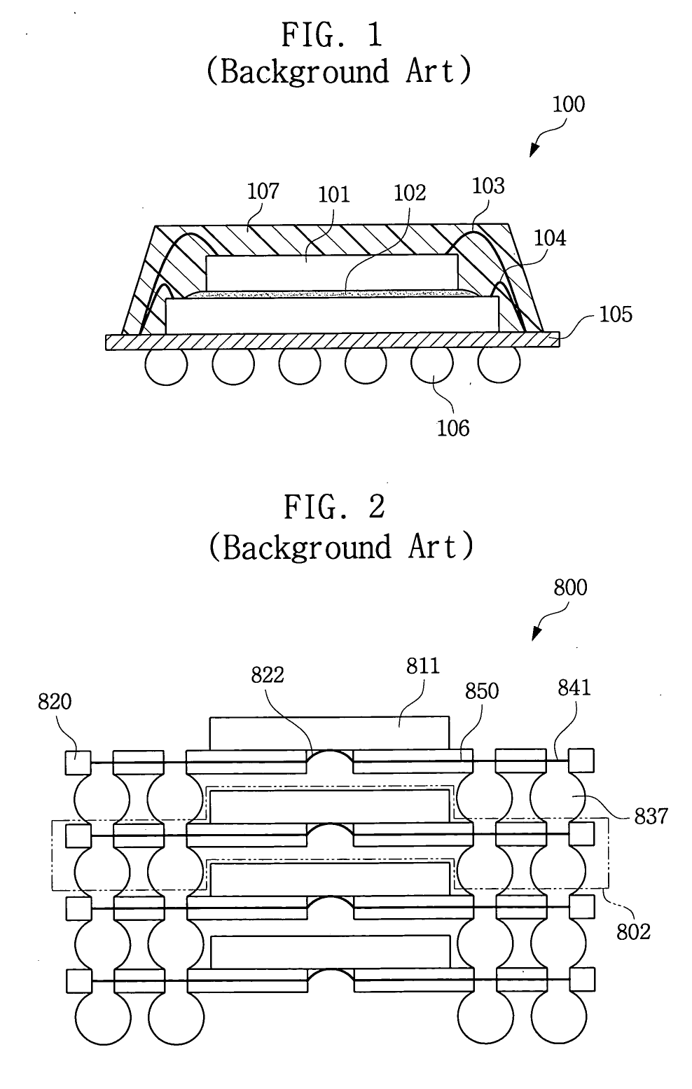

FIG. 2 is a cross-sectional view schematically showing a conventional package stack of ball grid array (BGA) package, according to the Background Art.

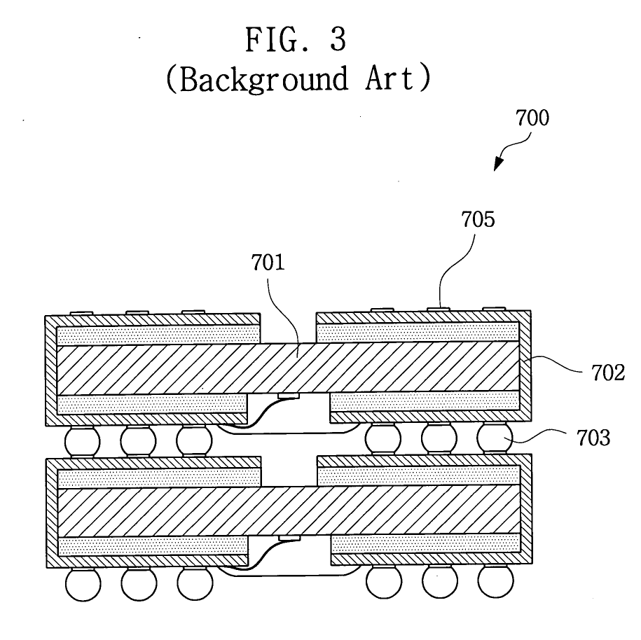

FIG. 3 is a cross-sectional view schematically showing another stack of BGA packages, according to the Background Art.

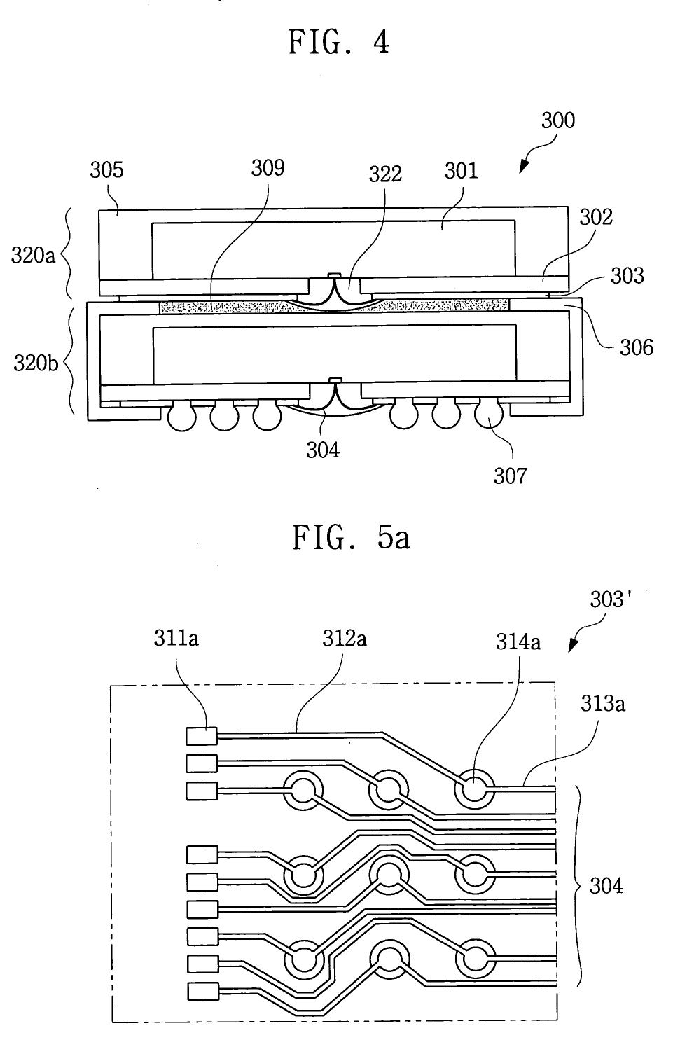

FIG. 4 is a cross-sectional view schematically showing a package stack of area array type packages having center pad type chips in accordance with at least one embodiment of the present invention.

FIGS. 5A and 5B are plan views showing two examples of substrate wiring patterns of the area array type packages shown in FIG. 4, according to at least one other embodiment of the present invention, respectively.

FIG. 6 is a cross-sectional view schematically showing a package stack of area array type packages in accordance with at least one other embodiment of the present invention.

FIG. 7 is a cross-sectional view schematically showing a package stack of area array type packages in accordance with at least one other embodiment of the present invention.

FIG. 8 is a cross-sectional view schematically showing a package stack of area array type packages having edge pad type chips in accordance with at least one other embodiment of the present invention.

FIG. 9 is a plan view showing an example of substrate wiring patterns of the area array type packages shown in FIG. 8, in accordance with at least one other embodiment of the present invention.

FIG. 10 is a cross-sectional view schematically showing a package stack of area array type packages having center pad type chips and edge pad type chips in accordance with at least one other embodiment of the present invention.

FIGS. 11A to 11F are cross-sectional views sequentially showing a method for manufacturing a package stack of area array type packages in accordance with at least one other embodiment of the present invention.

FIGS. 12A and 12B are plan views schematically showing a flexible cable frame used for the manufacture of the package stacks shown in FIG. 11, in accordance with at least one other embodiment of the present invention.

FIGS. 13A to 13E are cross-sectional views sequentially showing a method for manufacturing a package stack of area array type packages in accordance with at least one other embodiment of the present invention.

The accompanying drawings are: intended to depict example embodiments of the invention and should not be interpreted to limit the scope thereof; and not to be considered as drawn to scale unless explicitly noted.

### DETAILED DESCRIPTION OF EXAMPLE EMBODIMENTS

The present invention will now be described more fully hereinafter with reference to the accompanying drawings, in which example embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art.

In the description, well-known structures and processes have not been shown in detail for the sake of brevity and to avoid obscuring the present invention. It will be appreciated that for simplicity and clarity of illustration, some elements illustrated in the figures have not necessarily been drawn to scale. For example, the dimensions of some of the elements are exaggerated relative to other elements for clarity. Like numerals are used for like and corresponding parts of the various drawings.

In developing the present invention, the following problem with the Background Art was recognized and at least one path to a solution was identified. Area array package 700 according to the Background Art suffers degraded electrical properties. In array area package 700, interconnection between the packages is established though flexible cables 702 and the solder balls 703. Therefore, inside signal balls of upper packages have longer interconnection paths. Furthermore, in the uppermost package, a certain long wiring pattern, not used for interconnection, acts as an open stub that may represent an obstacle to high operating speed. Additionally, solder balls 703 interposed between the packages are a prime cause leading to an increase in package stack height. At least one embodiment of the present invention solves this problem.

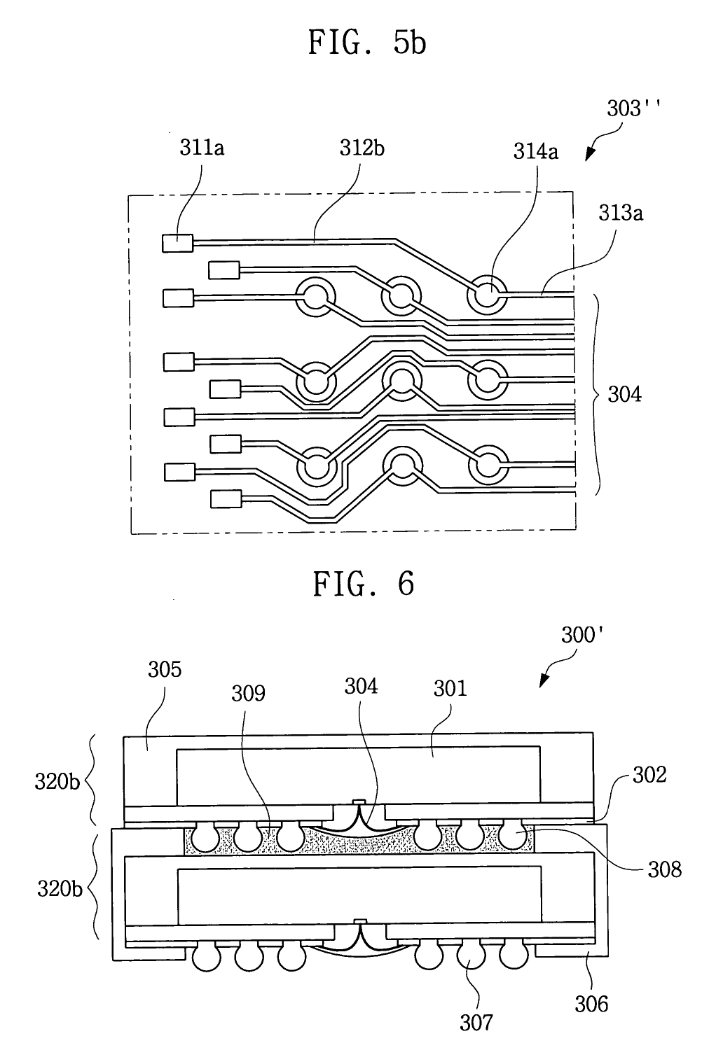

FIG. 4 schematically shows, in a cross-sectional view, a package stack 300 that includes two area array type packages, in accordance with one embodiment of the present invention. Each of packages 320a and 320b package shown in FIG. 4 has a center pad type chip (integrated circuit) 301. The chip 301 is attached on an upper face of a substrate 302 so that chip pads are exposed through an opening 322 formed in a central portion of substrate 302. Bond wires 304 electrically connect the chip pads of chip 301 to wiring patterns 303 formed on a lower face of substrate 302 through opening 322. An adhesive layer 309 can be interposed between the stacked packages 320i to enhance adhesion therebetween.

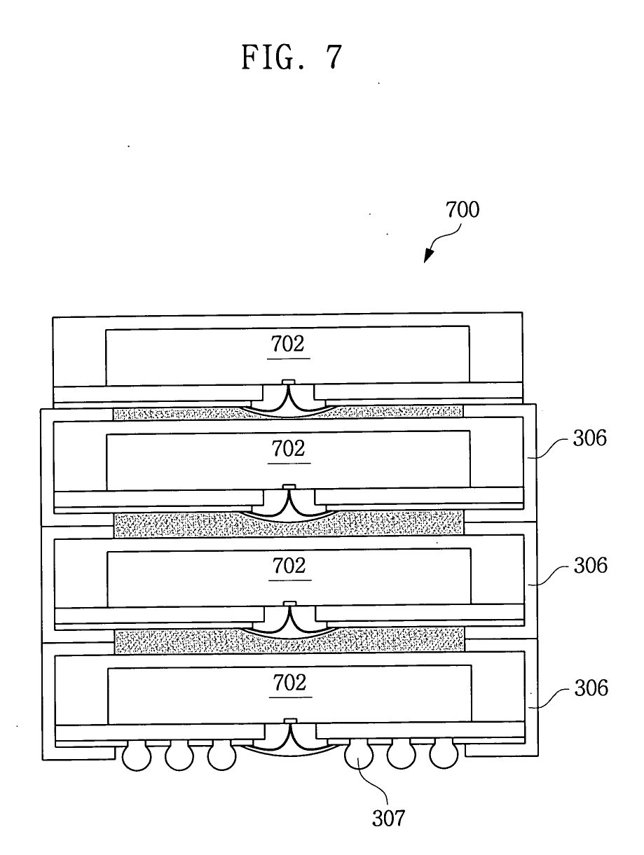

An example 303′ of wiring patterns 303 is shown in FIG. 5, according to at least one other embodiment of the present invention. Referring to FIG. 5A, wiring patterns 303 have first wirings 313a, second wirings 312a, ball pads 314a (a type of terminal pad), and connecting pads 311a. Each first wiring 313a is connected at one end to ball pad 314a and at the other end to one of bond wires 304 (shown in FIG. 4). Each second wiring 312a is connected at one end to ball pad 314a and at the other end to connecting pad 311a. Connecting pads 311a are arranged in a row near both edges of substrate 302. In this configuration, connecting pads 311a may act as substitutes for ball pads 314a to provide electrical paths from and to external systems.

FIG. 5B shows another example 303″ of wiring patterns 303, according to at least one other embodiment of the present invention. Wiring pattern 303″ has first wirings 313a, second wirings 312b, ball pads 314a, and connecting pads 311a. As compared with wiring patterns 303′ shown in FIG. 5A, wiring patterns 303″ in FIG. 5B have a staggered configuration of connecting pads 311b. As such, while second wirings 312b are similar to second wirings 312a, they differ in a manner reflecting the staggered arrangement of connecting pads 311a. This configuration can increase the density of connecting pads 311b as well as the distance between adjacent connecting pads 311b.

Returning to FIG. 4, electrical interconnection between the stacked packages 320i is established by a flexible cable 306. Flexible cable 306 has conductive patterns (not shown) each of which is joined at both ends to connecting pads (311a, e.g., in FIG. 5a) on the stacked packages 320i. The conductive pattern of flexible cable 306 and connecting pads 311a are connected in a known manner such as soldering.

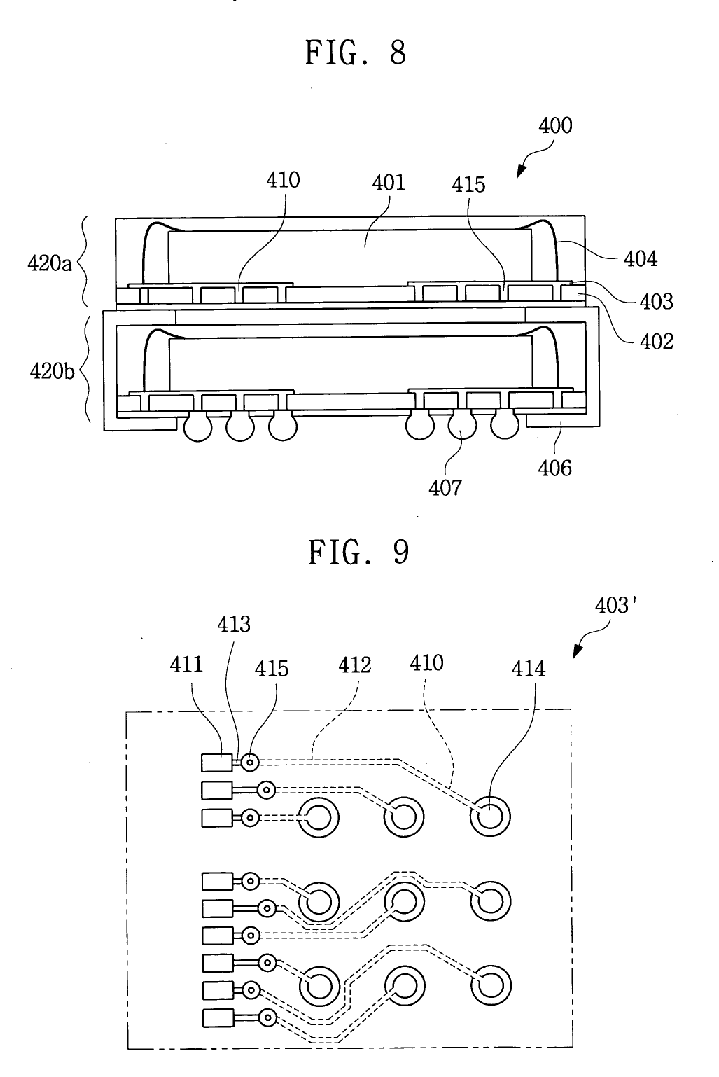

To reduce the total height of package stack 300, external connection terminals 307, e.g., solder balls, can be formed only on the lowermost package, as is the circumstance of FIG. 4. Alternatively, as shown in FIG. 6 (according to at least one other embodiment of the present invention), other combinations of packages 320i can be arranged into variations of package stack 300, e.g., package stack 300′ of FIG. 6 to having two packages 320b.

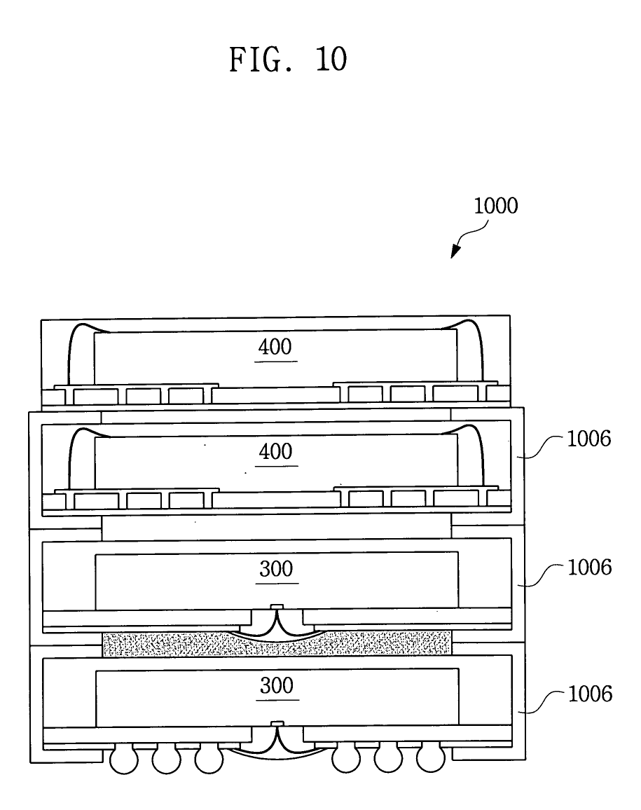

FIG. 7 shows a stack 700 of four individual package 702, according to at least one other embodiment of the present invention. As shown in FIG. 7, flexible cables 306 establish a direct electrical interconnection between the respective upper packages and external connection terminals 307 located at the bottom of stack 700 without passing through the wiring patterns on the intermediate packages. This reduces the length of interconnection and improves electrical properties of package stack 700.

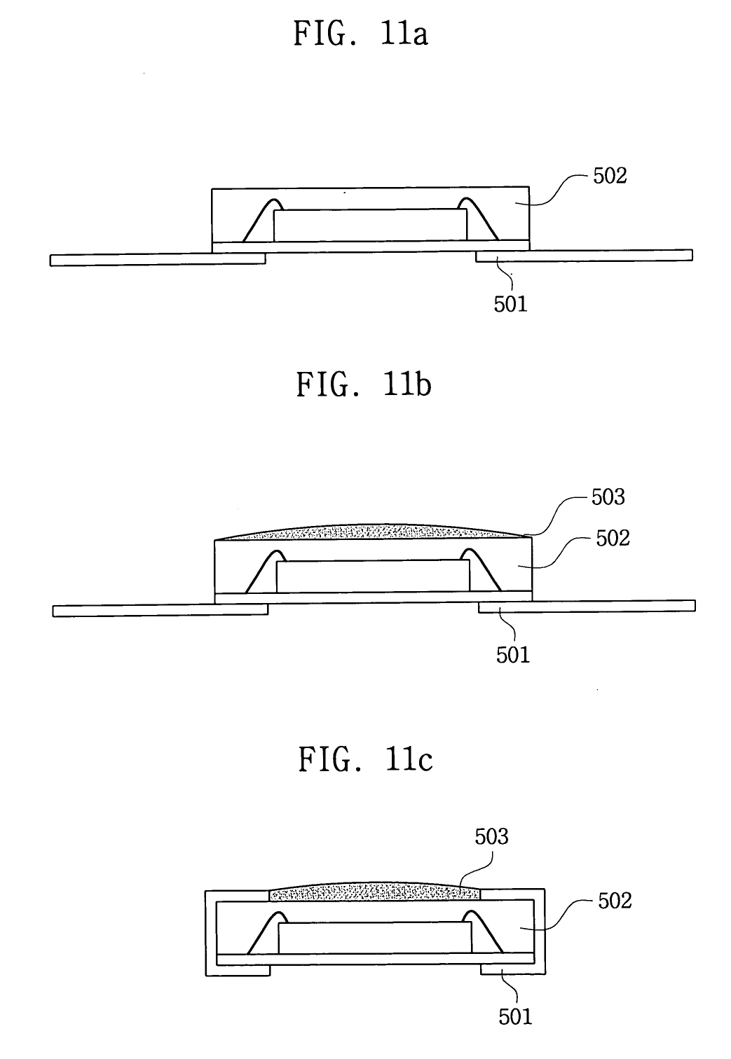

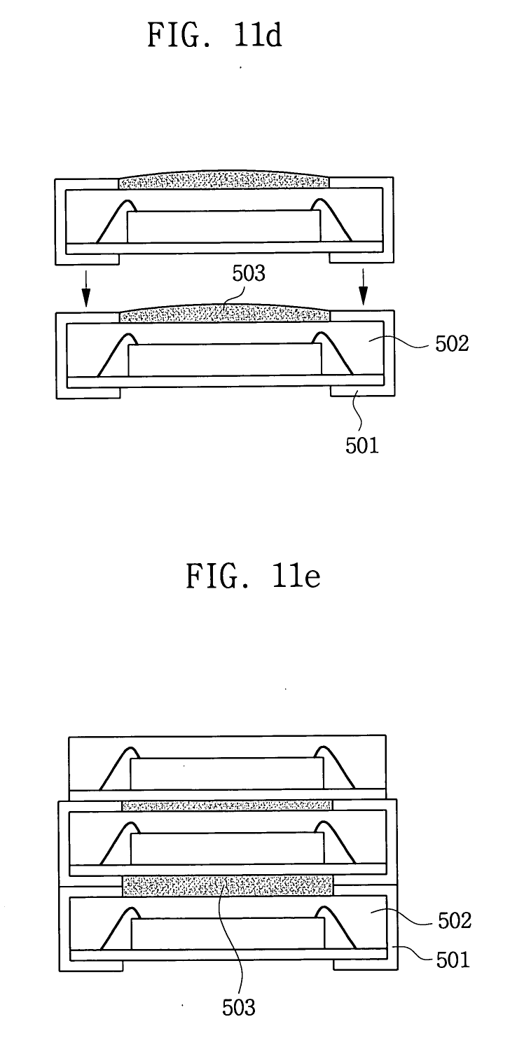

FIG. 8 shows a package stack 400 of two area array type packages in accordance with at least one other embodiment of the present invention. Each of packages 420a and 420b shown in FIG. 8 has an edge pad type chip 401. Chip 401 is attached on an upper face of a substrate 402 and electrically connected through bond wires 404 to wiring patterns 403 formed on substrate 402. Wiring patterns 403 have first wirings and second wirings, e.g., wiring patterns 403′ shown in FIG. 9 in accordance at least one other embodiment of the present invention, and can have a multi-layered configuration.

Referring to FIG. 9, wiring patterns 403′ have first wirings 412 formed on an upper face of substrate 402 and second wirings 413 formed on a lower face. First wirings 412 are connected to terminal pads, e.g., ball pads, 414 through first vias 410 and also to second wirings 413 through second vias 415. Second wirings 413 start from second vias 415 and terminate at connecting pads 411. As previously shown in FIG. 5B, connecting pads 411 alternatively may have a staggered configuration to increase the density thereof. Further, second vias 415 can be located in immediate proximity to connecting pads 411 so as to minimize lengths of second wirings 413.

Referring to FIGS. 8 and 9, second vias 415 reduce the length of interconnection paths between chip 401 and connecting pads 411. Further, respective connecting pads 411 of the individual packages are connected directly through a flexible cable 406. These features can reduce electrical interconnection from the respective stacked packages to external connection terminals 407 located at the bottom of stack 400, and can improve electrical properties of package stack 400.

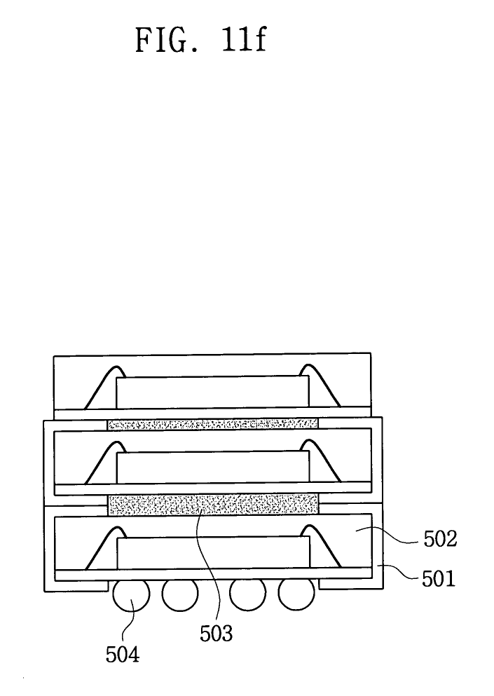

FIG. 10 shows a stack 1000, according to at least one other embodiment of the present invention. Stack 1000 includes two center-pad chip packages 300 as shown in FIG. 4 and two edge-pad chip packages 400 as shown in FIG. 8, in which respective packages 300 and 400 are electrically connected through flexible cables 1006.

In general, it should be understood by those skilled in the art that variations in type and/or arrangement of stacks relative to those discussed above are contemplated. Also, sample numbers of packages included in the stacks discussed above have been assumed for simplicity of discussion; other numbers of packages per stack are contemplated.

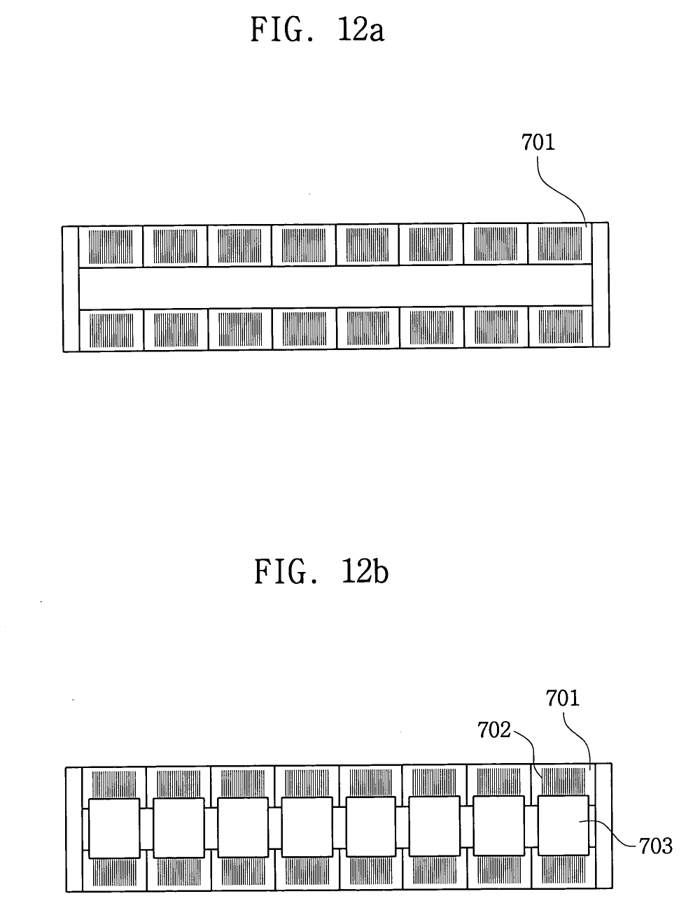

FIGS. 11A to 11F sequentially show, in cross-sectional views, a method for manufacturing a package stack of area array type packages in accordance with at least one other embodiment of the present invention.

Referring to FIG. 11A, a flexible cable 501 is disposed under an individual package 502. Package 502 has a plurality of connecting pads (not shown) on a bottom face thereof, and flexible cable 501 has a plurality of conductive patterns (not shown) on an upper face thereof. The conductive patterns and the connecting pads are connected to each other in a known manner such as by soldering.

Next, as shown in FIG. 11B, a non-conductive adhesive material 503 is provided on a top face of package 502. Further, as shown in FIG. 11C, flexible cable 501 is bent toward the top face of package 502 so as to extend around at least one side edge (here, two) of package 502.

Next, as shown in FIG. 11D, two or more packages 502 are placed one atop another to form a stack. In the stack, the respective conductive patterns on flexible cables 501 of stacked packages 502 are electrically connected to each other. As shown in alternative FIG. 11E, the uppermost package can do without a flexible cable. The connecting pads of the uppermost package are directly connected to the conductive patterns on flexible cable 501 of package 502 placed directly underneath.

Finally, as shown in FIG. 11F, external connection terminals such as solder balls 504 are formed on a bottom face of the lowermost package.

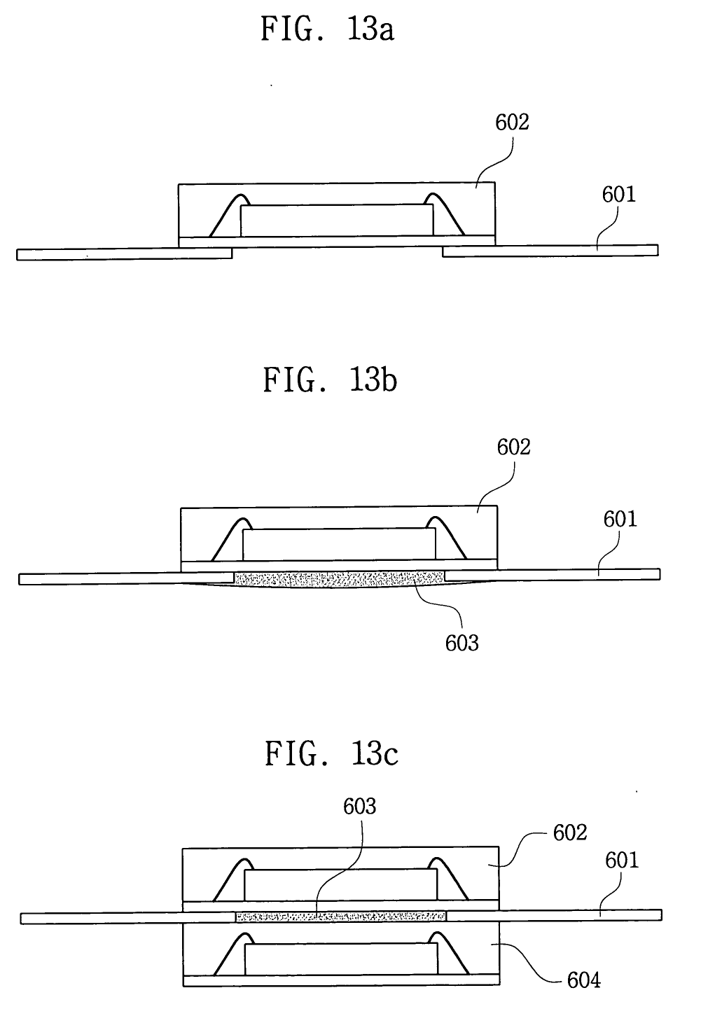

FIGS. 12A and 12B show, in plan views, a flexible cable frame 701 (according to at least one other embodiment of the present invention) in which the above-discussed flexible cables are configured. Flexible cable frame 701 facilitates the batch manufacture of the package stacks. As shown in FIG. 12B, area array type packages 703 are placed side by side on the respective flexible cables of frame 701 and connected at once to conductive patterns 702 of the flexible cables by soldering. Such batch processing can increase productivity.

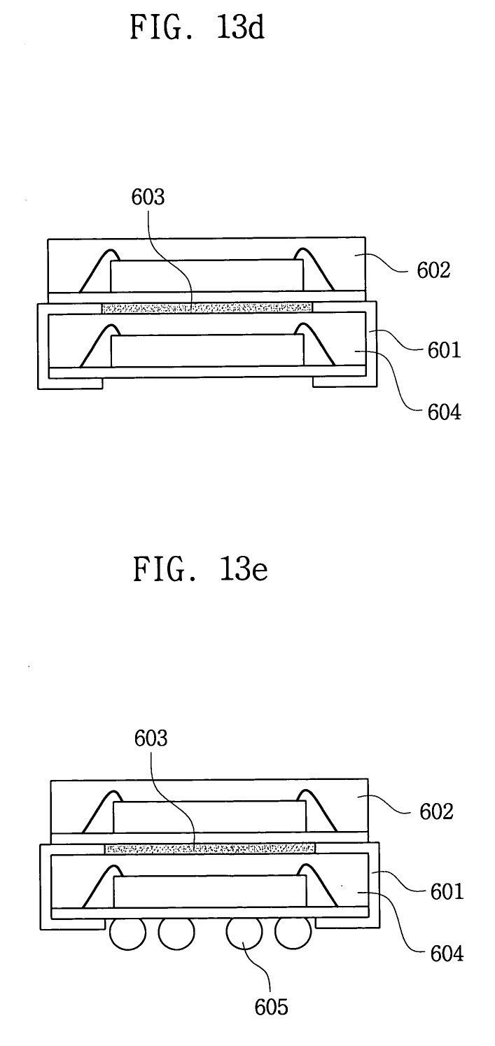

FIGS. 13A to 13E sequentially show, in cross-sectional views, a method for manufacturing a package stack of area array type packages in accordance with at least one other embodiment of the present invention.

As shown in FIG. 13A, a flexible cable 601 is disposed under an individual package 602 while connecting pads (not shown) of package 602 are electrically connected to conductive patterns (not shown) of flexible cable 601 (in a known manner, e.g., by soldering.

Next, as shown in FIG. 13B, an adhesive layer 603 is formed under package 602 and, as shown in FIG. 13C, another package 604 is attached to package 602 by adhesive layer 603.

Next, as shown in FIG. 13D, flexible cable 601 is bent downward so as to extend around at least one side edge (here, two) of underlying package 604 and then electrically connected to the connecting pads of underlying package 604.

Finally, as shown in FIG. 13E, external connection terminals such as solder balls 605 are formed under underlying package 604.

While this invention has been particularly shown and described with reference to example embodiments thereof, it will be understood by those skilled in the art that the same may be varied in many ways. Such variations are not to be regarded as a departure from the spirit and scope of the invention, and all such modifications are intended to be included within the scope of the invention.

1. An area array type package stack comprising:
at least two packages of area array type disposed to form a stack, each package including
a substrate having a first face and a second face opposing the first face, there being a plurality of terminal pads and a plurality of connecting pads formed on the second face, and
a semiconductor chip attached to the first face of the substrate and electrically connected to the terminal pads and the connecting pads; and
at least one flexible cable having a plurality of conductive patterns thereon extending around at least one side edge of a lower one of the at least two packages, and electrically coupling the connecting pads of the packages through the conductive patterns.

2. The area array type package stack of claim 1, wherein the semiconductor chip is a center pad type chip.

3. The area array type package stack of claim 2, wherein the substrate further has first wirings providing electrical paths coupling the semiconductor chip and the terminal pads and second wirings providing electrical paths coupling the semiconductor chip and the connecting pads.

4. The area array type package stack of claim 1, wherein the semiconductor chip is an edge pad type chip.

5. The area array type package stack of claim 4, wherein the substrate further has first wirings providing electrical paths coupling the semiconductor chip and the terminal pads, second wirings including vias providing electrical paths coupling the semiconductor chip and the connecting pads.

6. The area array type package stack of claim 5, wherein the vias are located in immediate proximity to the connecting pads.

7. The area array type package stack of claim 1, wherein the connecting pads are arranged in a straight row near an edge of the substrate.

8. The area array type package stack of claim 1, wherein the connecting pads are arranged in a staggered row near an edge of the substrate.

9. The area array type package stack of claim 1, further comprising a plurality of external connection terminals formed on the terminal pads of a lowermost package of the packages.

10. The area array type package stack of claim 1, further comprising a non-conductive adhesive layer interposed between adjacent lower and upper packages.

11. The area array type package stack of claim 1, wherein each area array type package is a ball grid array package.

12. A method for manufacturing an area array type package stack, the method comprising:
providing a first individual package of an area array type (AAT) on a flexible cable wherein connecting pads under the AAT package are electrically connected to conductive patterns on the flexible cable;
bending the flexible cable to extend around at least one side edge of the package; and
stacking a second individual AAT package on the first AAT package wherein connecting pads under the second package are electrically connected to the conductive patterns on the flexible cable.

13. The method of claim 12, further comprising providing a non-conductive adhesive material between the first and second packages.

14. The method of claim 12, further comprising forming a plurality of external connection terminals under the first package.

15. A method for manufacturing an area array type package stack, the method comprising:
providing a first package of an area array type (AAT) on a flexible cable wherein connecting pads under the package are electrically connected to conductive patterns on the flexible cable;
forming an adhesive layer under the first package;
attaching a second AAT package to the first package by the adhesive layer; and
bending the flexible cable to extend around at least one side edge of the second AAT package wherein connecting pads under the second package are electrically connected to the conductive patterns on the flexible cable.

16. The area array type package stack of claim 3, wherein the first wirings are formed on the second face of the substrate.

17. The area array type package stack of claim 5, where the first wirings are arranged on the first face of the substrate and the second wirings are arranged on the second face of the substrate.
